(19) United States
(12) Patent Application Publication
(10) Pub. No.: US 2021/0280756 A1
(43) Pub. Date: Sep. 9, 2021

(54) Radiation-Emitting Semiconductor Chip, Method for Producing a Plurality of Radiation-Emitting Semiconductor Chips, Radiation-Emitting Component and Method for Producing a Radiation-Emitting

(71) Applicant: OSRAM Opto Semiconductors GmbH, Regensburg (DE)

(72) Inventors: Ivar Tangring, Regensburg (DE); Korbinian Perzlmaier, Regensburg (DE)

(21) Appl. No.: 16/316,987

(22) PCT Filed: Jul. 25, 2017
(86) PCT No.: PCT/EP2017/068791

§ 371 Date: Jan. 10, 2019

(30) Foreign Application Priority Data
Jul. 28, 2016 (DE) 10 2016 113 969.6

(51) Int. Cl. H01L 33/60; H01L 33/56; H01L 33/00

(52) U.S. Cl. CPC H01L 33/60; H01L 33/56; H01L 2933/0058; H01L 2933/005; H01L 2933/0041; H01L 33/0095

(57) ABSTRACT

A radiation-emitting semiconductor chip, a method for producing a plurality of radiation-emitting semiconductor chips, a radiation-emitting component and a method for producing a radiation-emitting component are disclosed. In an embodiment, a radiation-emitting semiconductor chip includes a semiconductor layer sequence having an active layer configured to generate electromagnetic radiation, a substrate on which the semiconductor layer sequence is arranged and which is transparent to the electromagnetic radiation, a reflective layer disposed on a main surface of the substrate facing away from the semiconductor layer sequence, the reflective layer including a resin in which reflective particles are embedded and a transparent resin layer located between the main surface of the substrate and the reflective layer.

This patent application is a national phase filing under section 371 of PCT/EP2017/068791, filed Jul. 25, 2017, which claims the priority of German patent application 102016113969.6, filed Jul. 28, 2016, each of which is incorporated herein by reference in its entirety.

### TECHNICAL FIELD

A radiation-emitting semiconductor chip, a method for producing a plurality of radiation-emitting semiconductor chips, a radiation-emitting component and a method for producing a radiation-emitting component are specified.

### SUMMARY OF THE INVENTION

Embodiments provide a radiation-emitting semiconductor chip with increased radiation decoupling. In particular, the decoupling of the semiconductor chips should be increased when it is at least in part back-mounted on a lead frame. Further embodiments provide a method for producing a plurality of such semiconductor chips, a component comprising such a semiconductor chip and a method for producing a component comprising such a semiconductor chip.

According to one embodiment, the radiation-emitting semiconductor chip comprises a semiconductor layer sequence with an active layer, which is suitable for generating electromagnetic radiation. For example, the active layer generates blue and/or ultraviolet light.

Preferably, the semiconductor layer sequence is grown epitaxially. Likewise preferably, the semiconductor layer sequence is based on a nitride compound semiconductor material or is made of such material. Nitride based semiconductor materials are compound semiconductor materials that contain nitrogen, such as the already mentioned materials from the system, InₓAl_{y}Ga_{1-x-y}N where 0≤x≤1, 0≤y≤1 and x+y≤1.

According to another embodiment of the radiation-emitting semiconductor chip, the semiconductor layer sequence is arranged on a substrate, which is transparent for the electromagnetic radiation produced in the active layer. The term “transparent” is in this context that the as transparent designated element has at least 85%, preferably at least 90%, and particularly preferably at least 95%, or at least 99% of the respective electromagnetic radiation transmitted.

For example, the substrate is a growth substrate for the semiconductor layer sequence.

For example, the semiconductor layer sequence is based on a nitride compound semiconductor material and the substrate comprises sapphire or consists of sapphire. In this case sapphire is suitable as a growth substrate for a semiconductor layer sequence, which is based on a nitride compound semiconductor material. Particularly preferred the semiconductor layer sequence is grown on the substrate epitaxially. Further a sapphire substrate with advantage is normally transparent to visible electromagnetic radiation, in particular for blue light.

According to another embodiment of the radiation-emitting semiconductor chip a reflective layer is arranged on a main surface of the substrate, which faces away from the semiconductor layer sequence. The reflective layer is preferably part of the semiconductor chip, and, for example, cohesively bond to this. In particular, the semiconductor chip is preferably free of a component housing, a casting compound or another mechanical stabilizing element. Rather, the semiconductor chip is mechanically stable particularly preferably only by its substrate. In particular the reflective layer is preferably not part of the component housing or provided to fixate the semiconductor chip on a component housing or another carrier. Particularly preferably the reflective layer is freely accessible from the outside. Particularly preferred the reflective layer is formed diffusely reflective, for the light which is generated in the active layer. For example, the reflective layer is in direct contact with the main surface of the substrate. The reflective layer directs radiation of the active layer with advantage to a radiation exit surface of the semiconductor chip, the main surface of the substrate is opposite and thus increases the light yield from the semiconductor chip. Preferably the radiation exit surface of the semiconductor chip is parallel to the main surface of the substrate.

Specially preferred, the side surfaces of the semiconductor chip are free of the reflective layer. In this manner, an emission of the radiation generated in the active layer over the side surfaces of the semiconductor chip is possible.

Preferably the reflective layer is designed in an electrically insulating manner. According to a particularly preferred embodiment, the reflective layer of the semiconductor chip is composed of a resin, wherein reflective particles are embedded.

The resin has preferably a refractive index of not greater than 1.45.

According to one embodiment of the semiconductor chip, the reflective particles have a volume fraction of between 50 vol % and including 75 vol % in the reflective layer. Particularly preferably, the reflective particles have a volume fraction of between 60 vol % and including 75 vol % in the reflective layer. In this arrangement, the remaining volume of the reflective layer is particularly preferably formed by the resin. Such a reflective layer is advantageously particularly high filled with reflective particles. This has the advantage that, in addition to a high reflection effect of the reflective layer, the thermal conductivity of the reflective layer compared to an unfilled resin layer is increased. In this manner, produced heat during the operation of the semiconductor chip can be dispensed better to an underlying material.

Particularly preferably, the reflective particles have a refractive index of at least 2.2.

According to another embodiment of the semiconductor chip, the reflective particles have a diameter between 100 nanometers and including 500 nanometers.

According to a particularly preferred embodiment of the semiconductor chips, the resin is silicone and the reflective particles are titanium oxide particles. Particularly preferably the reflective layer is composed of silicone, in which the titanium oxide particles are embedded.

Furthermore the reflective layer comprises particularly preferably a thickness between 5 micrometers and including 15 micrometers.

Particularly preferably, the reflective layer has a thermal conductivity of between 1 w/mK and including 2 w/mK. This is opposite to the heat conductivity of a resin layer composed of silicone without particle filling, which has a heat conductivity about less than 0.2 w/mK, significantly increased. A heat conductivity of between 1 w/mK and including 2 w/mK can be normally achieved, for example, with a reflective layer, wherein the reflective particles have a volume fraction between 50 vol % and 75 vol %.

According to another embodiment of the radiation-emitting semiconductor chip, a further transparent resin layer is provided between the main surface of the substrate and the reflective layer. Wherein the transparent resin layer may, for example, be a silicone layer. The transparent resin layer can be formed of the same resin, which is also used for the reflective layer. Particularly preferably, the transparent resin layer has a refractive index which is not greater than 1.45.

Particularly preferably the transparent resin layer is applied in direct contact to the main surface of the substrate and the reflective layer is applied to the transparent resin layer in direct contact. The transparent resin layer has the effect that radiation-emitted by the active layer and incident on the reflective layer sees an average refractive index of the resin of the reflective layer and the particles of the reflective layer and therefore penetrates the reflective layer instead of being reflected, as desired.

Preferably, the transparent resin layer formed as thin as possible. A preferred lower limit of the thickness of the transparent resin layer is in this case in the half of the wavelengths of the radiation-emitted by the active layer. According to one embodiment of the semiconductor chip, the transparent resin layer has a thickness between 150 nanometers and including 1 micrometer. For example, the transparent resin layer has a thickness between 500 nanometers and including 1 micrometer.

The refractive index of the transparent resin layer is particularly preferably between and including 1.33 and including 1.4.

In the case of a very advantageous embodiment of the semiconductor chip, a transparent resin layer of silicone, having a thickness of about 1 micrometer, is applied in direct contact on the main surface of the substrate. On the transparent resin layer the reflective layer, with a thickness of about 10 micrometer, is applied in turn in direct contact. Here the reflective layer is formed from a silicone, wherein the titanium dioxide particles with a volume fraction of about 75% are embedded.

According to another embodiment, the radiation-emitting semiconductor chip further comprises a Bragg mirror. The Bragg mirror is particularly preferably between the main surface of the substrate and the reflective layer, or between the main surface of the substrate and the transparent resin layer.

A preferred embodiment of the semiconductor has in direct contact on the main surface of the substrate a Bragg mirror on, on which, the reflective layer is arranged in direct contact. Alternatively, it is also possible, that the main surface of the substrate is arranged in direct contact with the Bragg mirror, wherein the transparent resin layer is also applied on the Bragg mirror in direct contact. Particularly preferably the transparent resin layer is applied in turn in direct contact on the reflective layer.

According to one embodiment of the semiconductor chip, on a main surface of the semiconductor layer sequence, a conversion layer is applied, facing away from the substrate, the mentioned conversion layer is suitable to convert radiation of the active layer of a first wavelength range into electromagnetic radiation of a second wavelength range. The first wavelength range is different from the second wavelength range. For example, the conversion layer converts blue radiation of the active layer partially in yellow and/or red and/or green radiation, so that the semiconductor chip emits white light during operation.

In a method for producing a plurality of radiation-emitting semiconductor chip firstly a substrate wafer is provided, on which a semiconductor layer sequence is arranged. The semiconductor layer sequence comprises an active layer, which is adapted to generate electromagnetic radiation. On a main surface of the semiconductor layer sequence which faces away from the substrate wafer, electrical contacts are arranged, by means of which the active layer can be supplied with power.

If appropriate, the substrate wafer is thinned on a suitable thickness before or after the application of the semiconductor layer sequence. The thickness of the substrate wafer is preferably between 150 micrometers and including 1 millimeter.

The substrate wafer is preferably transparent for the radiation of the active layer. The substrate wafer can also have the same properties and attributes, as the substrate. The substrate wafer has with respect to the substrate only a larger surface, since the latter to the end of the method is separated, so that from the substrate wafer a plurality of substrates is produced. For example, the substrate wafer has been used as a growth substrate for the semiconductor layer sequence. It is preferred that the substrate wafer is a sapphire substrate wafer.

In a next step, fracture nucleations are introduced into the substrate wafer along separation lines. Preferably two directly adjacent separation lines are arranged in each case precisely between two electrical contacts. The separation lines are initially imaginary virtual lines along which the semiconductor chips are later separated. For introducing the fracture nucleations, for example, a laser can be used. For example, the method for the introduction of the fracture nucleations into the substrate wafer is a stealth dicing method.

In a next step, a reflective layer is applied on a main surface of the substrate wafer, particularly preferably over the entire surface. Finally, a mechanical breaking of the substrate wafer along the separation lines takes place, so that a plurality of radiation-emitting semi-conductor chips is produced. Preferably, the breaking along the separation lines takes places after the application of the reflective layer. Thereby, the reflective layer is preferably cured, so that no material of the reflective layer can pass on the side surfaces of the finished semiconductor chips. Particularly preferably, the breaking is the last method step the present method.

In accordance to one embodiment of the method, a transparent resin layer is arranged on the main surface of the substrate wafer after the introduction of the fracture nucleations and before the application of the reflective layer, preferably over the entire surface.

According to a further version of the method, the reflective layer and/or the transparent resin layer are applied by spray coating. Spray coating can be used in particular to produce layers with a very uniform thickness. In particular, the thickness of the reflective layer and/or the thickness of the transparent resin layer does not deviate more than 5% from an average value.

In a spray coating method, liquid resin, which is provided with the reflective particles during producing the reflective layer, is first applied to the surface to be coated by spraying and then hardened.

According to another version of the method, mechanical breaking also separates the reflective layer as well as all other layers on the substrate wafer. Preferably no pre-treatment of the reflective layer, such as scribing or ablation along the separation lines, takes place before breaking. Preferably a sharp edge of the reflective layer or of the other layers on the substrate wafer is created during mechanical breaking.

Furthermore, it is also possible that at least the reflective layer is scored, ablated or removed along the separation lines before breaking. Scoring, ablation or removal can, for example, be carried out using a laser treatment such as a picosecond laser or a water jet guided laser, a saw blade or a blade.

For example, the radiation-emitting semiconductor chip is suitable for use in a radiation-emitting component. For example, the radiation-emitting semiconductor chip is inserted into the recess of a component housing. The recess is advantageously provided with a potting compound.

A bottom surface of the recess of the component housing is preferably formed partly by the surface of a lead frame embedded in a housing body. The surface of the lead frame is particularly preferably made of silver. The semiconductor chip with a rear side opposite a radiation exit surface is preferably applied to the surface of the lead frame. The described semiconductor chip has the advantage that the reflection of radiation-emitted to the back of the semiconductor chip is reflected not only by the surface of the lead frame to the radiation exit surface of the semiconductor chip, but also at least by the reflective layer.

To produce a radiation-emitting component, for example, a described semiconductor chip can be glued into the recess of a component housing. The side surfaces of the semiconductor chip are particularly preferred to be free of adhesive. This has the advantage that the refractive index of the used adhesive can essentially be freely selected.

Alternatively, it is also possible that the adhesive has a high refractive index, preferably at least of 1.5. This has the advantage that it is not absolutely necessary to keep the side surfaces of the semiconductor chip free of adhesive.

Luminescent particles are particularly preferred introduced into the encapsulation material, which form a conversion layer by sedimentation on a radiation exit surface of the semiconductor chip and on a bottom surface of the recess.

The luminescent particles are particularly suitable for converting electromagnetic radiation of the semiconductor chip from a first wavelength range at least partially into a second wavelength range. For example, the semiconductor chip emits blue light, which is at least partially converted into yellow light by the luminescent particles.

For the luminescent particles, for example, one of the following materials is suitable: rare earth doped garnets, rare earth doped alkaline earth sulfides, rare earth doped thiogallates, rare earth doped aluminates, rare earth doped silicates, rare earth doped orthosilicates, chlorosilicates doped with rare earths, alkaline earth silicon nitrides doped with rare earths, oxynitrides doped with rare earths, aluminum oxynitrides doped with rare earths, silicon nitrides doped with rare earths, sialons doped with rare earths.

One idea of the present application is to apply a very thin highly reflective layer to the backside main surface of a transparent substrate of a semiconductor chip. The reflective layer is preferably made of a resin such as silicone, into which reflective particles, such as titanium oxide particles, are introduced with a high degree of filling. Such a reflective layer, for example, has the advantage over a Bragg mirror of having a high thermal conductivity and at the same time a very high reflectivity for visible, in particular blue light, of the active layer. For example, a particle-filled resin layer can have a reflectivity greater than 97% for blue light. This value is higher than that of conventional metal mirrors.

The one particle-filled resin layer as a reflective layer can still be applied with advantage by spray coating. This application method usually allows a very good control of the thickness of the applied layer. Furthermore, due to its low thickness, the reflective layer can be cut into a large number of individual semiconductor chips by forming a sharp edge when mechanically breaking a chip wafer composite.

Characteristics and configurations which are described here only with the semiconductor chip may also be formed in the method for producing the semiconductor chip, the component and the method for producing the component, and vice versa.

### BRIEF DESCRIPTION OF THE DRAWINGS

Further advantageous forms of embodiments and further development of the invention result from the examples of execution described in the following in connection with the Figures.

FIGS. 1 to 8 show schematic sectional views of a method for producing a large number of radiation-emitting semiconductor chips according to a first embodiment.

FIGS. 9 to 12 show schematic sectional views of a method for producing a radiation-emitting component according to an embodiment.

FIG. 13 shows a schematic sectional view of how a radiation-emitting component functions.

Same, similar or similarly acting elements are provided with the same reference signs in the Figures. The Figures and the proportions of the elements shown in the Figures shall not be regarded as to be scaled. Rather, individual elements, in particular layer thicknesses, may be exaggeratedly large for better representability and/or better understanding.

### DETAILED DESCRIPTION OF ILLUSTRATIVE EMBODIMENTS

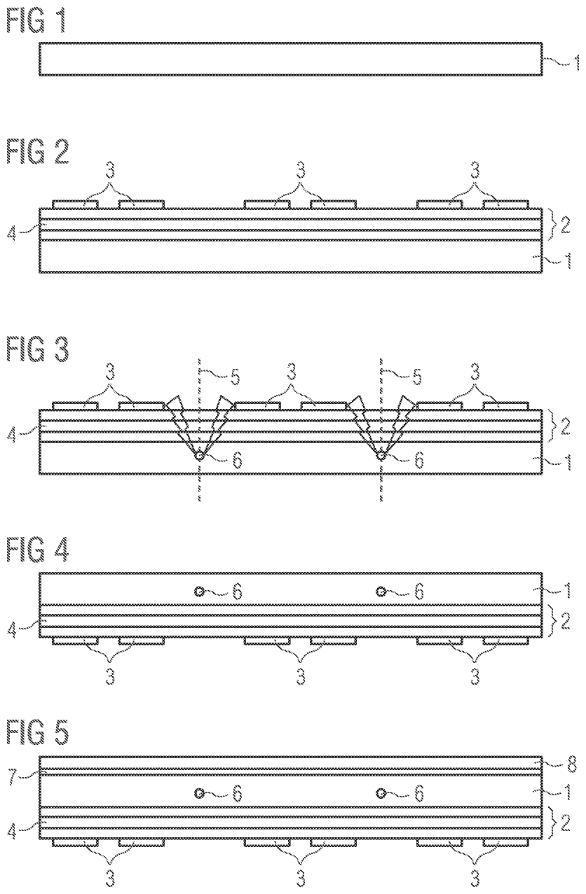

In the method described in the example of FIGS. 1 to 8, a substrate wafer 1 is provided (FIG. 1). The substrate wafer 1 is made of sapphire. Then, as schematically shown in FIG. 2, an epitaxial semiconductor layer sequence 2 is epitaxially grown on the substrate wafer 1 and a plurality of electrical contacts 3 are applied to a main surface of the semiconductor layer sequence 2 facing away from the substrate 1.

The semiconductor layer sequence 2 comprises an active layer 4, which is suitable for generating blue light during operation of the finished semiconductor chips. The sapphire substrate wafer 1 is transparent to the blue light of the active layer 4. The epitaxial semiconductor layer sequence 2 is preferably based on a nitride compound semiconductor material.

In a next step, fracture nucleations 6 are introduced into the substrate wafer 1 along separation lines 5 using a laser (FIG. 3). Exactly two electrical contacts 3 are arranged between two directly adjacent separation lines 6.

After the fracture nucleations 6 have been introduced, a Bragg mirror 7 is now applied over its entire surface in direct contact to a main surface of the substrate wafer 1, which faces away from the semiconductor layer sequence 2 (FIG. 4) in the embodiment shown in FIGS. 1 to 8.

In a further step, a transparent resin layer 8 is arranged on the Bragg mirror 7 in direct contact, for example, by spray coating (FIG. 5). The transparent resin layer 8, for example, is made of silicone.

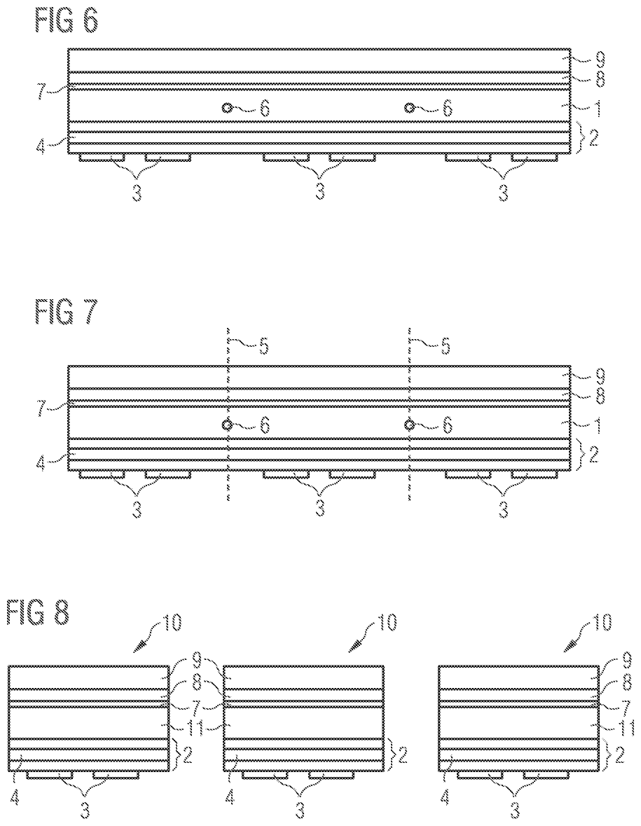

Finally, in direct contact with the transparent resin layer 8, a reflective layer 9 is applied over the entire surface, preferably also by spray coating. The reflective layer 9 is formed from a resin such as silicone in which reflective particles are incorporated. The reflective particles are preferably made of titanium oxide (FIG. 6).

The transparent resin layer 8 is particularly preferred to be cured before the reflective layer 9 is applied. Likewise, the reflective layer 9 is preferably cured after application.

Finally, the chip composite is separated into a large number of radiation-emitting semiconductor chips 10 by mechanical breaking along the separation lines 5 (FIG. 7).

Finally, FIG. 8 shows the finished semiconductor chips 10, as they are produced in the method according to the example in FIGS. 1 to 8.

Each semiconductor chip 10 has a substrate 11 on which an epitaxial semiconductor layer sequence 2 with an active layer 4 is arranged. The active layer 4 is suitable for emitting blue light. On a main surface of the semiconductor layer sequence 2, which is facing away from the substrate 11, two electrical contacts 3 are arranged, which serve for the electrical contacting of the active layer 4.

A Bragg mirror 7 is applied in direct contact to a main surface of substrate 1 that faces away from the semiconductor layer sequence 2. In direct contact with the Bragg mirror 7, a transparent resin layer 8, made of silicone, is also arranged. Finally, a reflective layer 9 is arranged in direct contact on the transparent resin layer 8. The reflective layer 9 is made of a silicone in which titanium dioxide particles are incorporated.

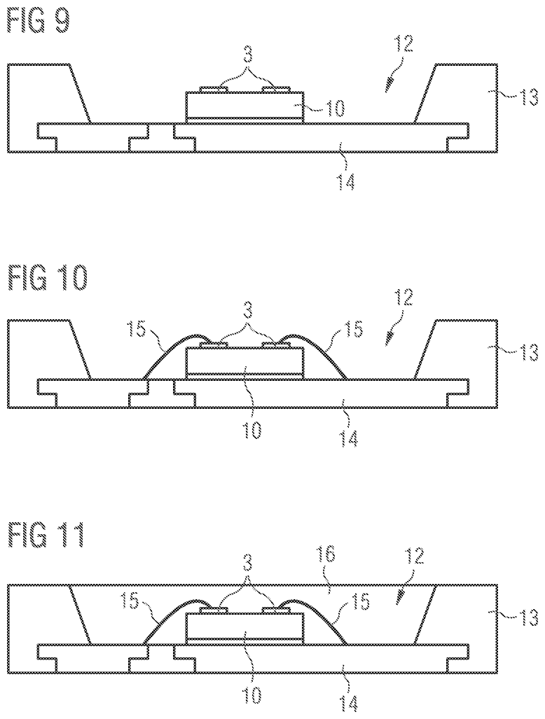

In the method described in the embodiments of FIGS. 9 to 12, a semiconductor chip 10 is arranged on the bottom surface of a recess 12 of a component housing 13. Unlike the semiconductor chip shown in FIG. 8, the semiconductor chip does not have a Bragg mirror 7, but only a transparent resin layer 8 and a reflective layer 9 (FIG. 9). The component housing 13 has a lead frame 14 which is embedded in a housing body. The housing body, for example, is formed by an epoxy resin. The lead frame 14, for example, is made of metal such as silver. The semiconductor chip 10 is mounted with a main surface of the reflective layer 9 on a part of the bottom surface of the recess 12 formed by the lead frame 14. The semiconductor chip 10 is particularly preferred to be attached to the bottom surface of the recess 12 by gluing.

The adhesive has either a comparatively low refractive index or a comparatively high refractive index. If a comparatively low refractive index is used, the sides of the semiconductor chip 10 are particularly preferably to be free of an adhesive. This is not necessary when using an adhesive with a higher refractive index.

In a further step, shown schematically in FIG. 10, the front electrical contacts 3 of the semiconductor chip 10 are each electrically conductively connected with a bonding wire 15 to two different areas of the lead frame 14. The two areas of the lead frame 14, each provided with a bonding wire 15, are electrically insulated from each other by one area of the housing body.

In the next step, which is schematically shown in FIG. 11, the recess 12 of the component housing 13, in which the semiconductor chip 10 is arranged, is provided with a potting 16. The potting 16 is made of a silicone in which luminescent particles are incorporated.

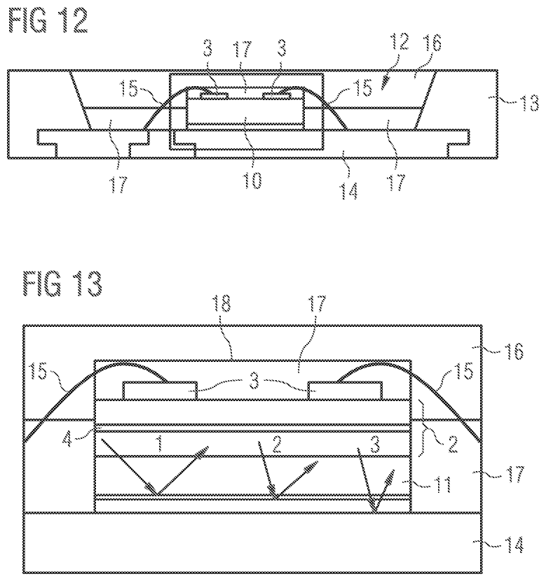

In a next step, schematically shown in FIG. 12, the phosphor particles sediment and form a dense conversion layer 17 on a main surface of the semiconductor chip 10 and on those portions of the bottom surface of the recess 12 that are freely accessible.

FIG. 13 schematically shows the marked section of the radiation-emitting component of FIG. 12. FIG. 13 is used to explain some details of the semiconductor chip 10 in more detail.

Due to the comparatively high refractive index of sapphire substrate 11, it is possible that light generated in the active layer 4 and emitted to a main rear surface of substrate 11 is totally reflected inside the semiconductor chip 10. The higher the refractive index difference between substrate 11 and the surrounding material, the higher the probability of total reflection at the interfaces of the sapphire substrate. By applying a thin transparent resin layer 8 to the back main surface of substrate 11, e.g., of a clear silicone with a refractive index as low as possible, total reflection can be maximized at the back main surface of substrate 11, so that radiation from the active layer 4 emitted to the back main surface of substrate 11 is deflected to a radiation exit surface 18 of the semiconductor chip 10. The thickness of the transparent resin layer 8 is preferably between 0.5 micrometers and 1 micrometer.

In direct contact with the transparent resin layer 8, a reflective layer 9 of silicone with titanium oxide particles is applied. The transparent resin layer 8 has a preferred thickness of about 10 micrometers. If radiation from the active layer 4 penetrates through the transparent resin layer 8, it can be reflected back through the diffusely reflective layer 9. The thickness of the reflective layer 9 is a compromise between thermal conductivity and reflectivity.

Due to the reflective layer 9, the amount of radiation from the semiconductor chip 10 impinging on the lead frame 14 is reduced. Since the lead frame 14 usually has a comparatively low reflectivity, the loss of radiation can be reduced.

Furthermore, it is possible that a Bragg mirror 7 is arranged between the substrate 11 and the transparent resin layer 9. If a Bragg mirror 7 is present, it generally defines the internal reflection within the semiconductor chip 10.

The invention is not limited to these by the description on the basis of the embodiments. Rather, the invention includes each new feature as well as each combination of features, which in particular includes each combination of features in the claims, even if that feature or combination itself is not explicitly stated in the claims or embodiments.

1-19. (canceled)

20. A radiation-emitting semiconductor chip comprising:
a semiconductor layer sequence having an active layer configured to generate electromagnetic radiation;
a substrate on which the semiconductor layer sequence is arranged and which is transparent to the electromagnetic radiation;
a reflective layer disposed on a main surface of the substrate facing away from the semiconductor layer sequence, the reflective layer comprising a resin in which reflective particles are embedded; and
a transparent resin layer located between the main surface of the substrate and the reflective layer.

21. The radiation-emitting semiconductor chip according to claim 20, wherein side surfaces of the semiconductor chip are free of the reflective layer.

22. The radiation-emitting semiconductor chip according to claim 20, wherein the reflective particles in the reflective layer have a volume between 50 vol % and 75 vol % inclusive.

23. The radiation-emitting semiconductor chip according to claim 20, wherein the reflective particles have a refractive index of at least 2.2.

24. The radiation-emitting semiconductor chip according to claim 20, wherein the reflective particles comprise titanium oxide, and wherein the resin is silicone.

25. The radiation-emitting semiconductor chip according to claim 20, wherein the reflective layer has a thickness between 5 micrometers and 15 micrometers inclusive.

26. The radiation-emitting semiconductor chip according to claim 20, wherein the reflective layer has a thermal conductivity between 1 W/mK and 2 W/mK inclusive.

27. The radiation-emitting semiconductor chip according to claim 20, wherein the transparent resin layer has a thickness between 150 nanometers and 1 micrometer inclusive.

28. The radiation-emitting semiconductor chip according to claim 20, wherein the transparent resin layer is disposed in direct contact to the main surface of the substrate and the reflective layer is disposed in direct contact to the transparent resin layer.

29. The radiation-emitting semiconductor chip according to claim 20, further comprising a Bragg mirror disposed between the main surface of the substrate and the reflective layer or between the main surface of the substrate and the transparent resin layer.

30. A radiation-emitting component comprising:
the radiation-emitting semiconductor chip according to claim 20.

31. The radiation-emitting component according to the claim 30, wherein the semiconductor chip is located in a recess of a component housing, and wherein the component housing comprising a potting compound.

32. A method for producing a radiation-emitting component, the method comprising:
gluing the semiconductor chip according to claim 20 into a recess of a component housing; and
encapsulating the semiconductor chip.

33. The method according claim 32, further comprising:
introducing phosphor particles into a encapsulation material; and
forming a conversion layer by sedimentation on a radiation exit surface of the semiconductor chip and on a bottom surface of the recess.

34. A method for producing a plurality of radiation-emitting semiconductor chips, the method comprising:
providing a substrate wafer having disposed thereon a semiconductor layer sequence having an active layer configured to generate electromagnetic radiation, wherein the substrate wafer is transparent to the electromagnetic radiation;
introducing fracture nucleations in the substrate wafer along separation lines;
applying a reflective layer to a main surface of the substrate wafer over its entire area; and
mechanically breaking the substrate wafer along the separation lines to form a plurality of radiation-emitting semiconductor chips,
wherein a transparent resin layer is disposed between the main surface of the substrate and the reflective layer.

35. The method according to claim 34, wherein the transparent resin layer is arranged over the entire surface on the main surface of the substrate wafer after the fracture nucleations is introduced and before the reflective layer is applied.

36. The method according to claim 34, wherein the reflective layer and/or the transparent resin layer are applied by spray coating.

37. The method according to claim 34, wherein a sharp edge of the reflective layer and/or the transparent resin layer is formed during breaking.

38. The method according to claim 34, wherein at least the reflective layer is scored, ablated or removed along the separation lines prior to breaking.

39. The method according claim 34, wherein the reflective layer is freely accessible from the outside.

40. A radiation-emitting semiconductor chip comprising:
a semiconductor layer sequence having an active layer configured to generating electromagnetic radiation;
a substrate on which the semiconductor layer sequence is arranged and which is transparent to the electromagnetic radiation generated in the active layer;
a reflective layer disposed on a main surface of the substrate facing away from the semiconductor layer sequence, the reflective layer being formed of a resin in which reflective particles are embedded; and
a transparent resin layer located between the main surface of the substrate and the reflective layer,
wherein the reflective layer is freely accessible from the outside, and
wherein the reflective layer has a thickness between 5 micrometer and 15 micrometer, inclusive.
